(19) United States
(12) Patent Application Publication
(10) Pub. No.: US 2018/0090769 A1
(43) Pub. Date: Mar. 29, 2018

(54) ENERGY DEVICE INCLUDING HALOGENATED CARBON MATERIAL AND METHOD FOR PREPARING THE SAME

(71) Applicant: KOREA INSTITUTE OF SCIENCE AND TECHNOLOGY, Seoul (KR)

(72) Inventors: Han Ik JO, Jeollabuk-do (KR); Cheol-Ho LEE, Jeollabuk-do (KR); Gil Seong KANG, Jeollabuk-do (KR); Younki LEE, Jeollabuk-do (KR); Sung Ho LEE, Jeollabuk-do (KR); Seong Mu JO, Jeollabuk-do (KR); Sang Jun YOUN, Jeollabuk-do (KR)

(21) Appl. No.: 15/715,159

(22) Filed: Sep. 26, 2017

(30) Foreign Application Priority Data
Sep. 27, 2016 (KR) 10-2016-0124201

(51) Int. Cl. H01M 4/90; H01M 4/58; H01G 11/68; H01L 51/00; H01L 51/50; C01B 32/184; C01B 32/194; C01B 32/198

(52) U.S. Cl. CPC H01M 4/9083; H01M 4/9016; H01M 4/582; H01G 11/68; C01B 32/198; H01L 51/5056; C01B 32/184; C01B 32/194; H01L 51/0045

(57) ABSTRACT

Prepared is a halogenated carbon material, which reduces a carbon material having an oxygen-based functional group by introducing a halogen gas or a mixed gas of a halogen gas and an inert gas into the carbon material having an oxygen-based functional group, and dopes a halogen into the carbon material. The resulting halogenated carbon material includes one or more selected from a group consisting of C—Y₂ and C—Y₃, and may be suitably for an energy device such as a fuel cell, a lithium ion battery, and a solar cell.

### CROSS-REFERENCE TO RELATED APPLICATION

This application claims the priority of Korean Patent Application No. 10-2016-0124201, filed on Sep. 27, 2016, and all the benefits accruing therefrom under 35 U.S.C. § 119, the contents of which in its entirety are herein incorporated by reference.

### BACKGROUND

### 1. Field

The present specification relates to an energy device including a halogenated carbon material and a method for preparing the same.

### 2. Description of the Related Art

Graphene is a two-dimensional nanomaterial having an atomic thickness, in which carbon atoms form a honeycomb structure having a hexagonal cyclic shape, and has been subjected to numerous studies as a next-generation electronic and electrode material due to a wide specific surface area (2,600 m²/g), excellent electrical conductivity (15,000 to 200,000 cm²/Vs) and permeability, and excellent chemical stability. In particular, the theoretical electron movement speed of graphene is nearly close to the speed of light, and the reason is because electrons flow in graphene as if the mass of the electron is zero due to the inherent peculiar band structure of graphene.

Examples of a method for preparing graphene include a chemical vapor deposition (CVD) method for making graphene by adsorbing carbon onto a substrate such as nickel or copper at high temperature, an epitaxial growth method for making graphene through a heat treatment of a crystal material including carbon, such as SiC, a mechanical exfoliation of graphite by using an adhesive tape, and the like, and a high-quality graphene may be made through the methods. However, these methods are difficult to be applied to electrode materials due to disadvantages in that preparation costs are high, it is difficult to achieve mass production, and it is difficult to adjust the thickness and control the form.

In contrast, a chemical exfoliation method which peels off graphite by widening the interlayer spacing through oxidation of graphite is suitable for mass production and application to an electrode material because a large amount of the material may be obtained in a powder state through an oxidizing agent, the material is easily chemically modified, and the material can be dispersed in an aqueous solution. A graphene oxide prepared by using the chemical exfoliation method is relatively easily chemically modified, and this is because chemical reactions easily occur from oxygen functional groups present in a large amount on the surface of graphene.

Meanwhile, an inherent band gap or catalytic activity is required to apply graphene. The technology most frequently used to adjust the band gap and impart the catalytic activity is a technology of doping heterogeneous elements, and the most widely used element is nitrogen. Methods for mixing a material which is a precursor of nitrogen, such as ammonia or urea, and melamine well with a graphene material, and then performing doping through a high heat treatment, or for doping nitrogen by using a reducing agent including nitrogen, such as hydrazine have been frequently studied, and studies using plasma have also been reported.

### REFERENCES OF THE RELATED ART

### Patent Documents

(Patent Document 1) U.S. 8,114,372

### Non-Patent Documents

(Non-Patent Document 1) Advanced Functional Materials, In-Yup Jeon, 2015, 25, 1170-1179

### SUMMARY

In an aspect, the present disclosure is directed to providing a novel material capable of being used while replacing an existing energy device material in an energy device such as a fuel cell, a secondary battery, and a solar cell.

Specifically, particularly in a fuel cell, the present disclosure is directed to providing a novel fuel cell electrode material which may show oxygen reduction characteristics close to those of platinum, and thus may replace platinum.

Further, particularly in a secondary battery, the present disclosure is directed to providing a novel lithium ion battery electrode material capable of solving disadvantages of existing carbon-based and metal electrodes by providing high storage capacity, high rate charge and discharge characteristics, and volume expansion suppression characteristics.

In addition, particularly in an organic or perovskite solar cell, the present disclosure is directed to providing a solar cell hole transporting layer material having particularly excellent hole transporting ability.

In another aspect, the present disclosure is directed to providing a method and a device, which chemically reduce a carbon material having an oxygen-based functional group, such as graphene oxide and simultaneously dope a halogen, and are capable of doping a halogen at a high concentration (for example, 30% or more based on the atomic ratio of halogen atoms to carbon atoms in the carbon material) within a very short period of time, for example, 60 seconds without using acid or laser arc discharge, a high-temperature and high-pressure plasma, and the like.

In still another aspect, the present disclosure is directed to providing a method and a device, which are capable of easily adjusting the doping amount by controlling the ratio of a halogen gas and an inert gas, the exposure time, and the like, and are also capable of doping halogen atoms onto the entire surface of a carbon material rather than a portion thereof.

In an exemplary aspect, the present disclosure provides an energy device including: a halogen (Y)-doped carbon material, in which the halogen-doped carbon material includes one or more selected from a group consisting of C—Y₂ and C—Y₃. Here, Y is a halogen such as, for example, F, Cl, Br, and I, and preferably F.

In an exemplary embodiment, the halogen-doped carbon material may be a halogen-doped carbon material including all of C—Y, C—Y₂, and C—Y₃.

In another exemplary embodiment, for the halogen-doped carbon material, an entire surface of the carbon material, which includes a basal plane and an edge, may be doped with a halogen.

In another exemplary embodiment, the halogen-doped carbon material may be a halogen-doped carbon material including C—Y, C—Y₂, and C—Y₃ on an edge and a basal plane.

In another exemplary embodiment, the carbon material may include an oxygen-based functional group at a predetermined content, for example, 3% or more or 3% to 35%.

In another exemplary embodiment, the carbon material may have an oxygen-based functional group, and may be one or more selected from a group consisting of graphene oxide, carbon nanotube oxide, carbon nanofiber oxide, activated carbon oxide, and graphite oxide.

In another exemplary embodiment, the energy device may be an energy device such as a fuel cell, a secondary battery, a fuel cell, and an electrochemical double layer capacitor, particularly preferably a fuel cell or a secondary battery or an organic/perovskite solar cell.

In another exemplary aspect, the present disclosure also provides a method for preparing a halogenated carbon material, the method comprising: introducing a halogen gas or a mixed gas of a halogen gas and an inert gas into the carbon material having an oxygen-based functional group, thereby reducing the carbon material having an oxygen-based functional group and doping a halogen into the carbon material. Here, the halogen is a halogen such as, for example, F, Cl, Br, and I, and preferably F.

In an exemplary embodiment, when a halogenation proceeds, etching of the carbon material is made not to proceed.

In another exemplary embodiment, the method may include: putting a carbon material having an oxygen-based functional group into a reactor; and halogenating the carbon material having an oxygen-based functional group by injecting a halogen gas or a mixed gas of a halogen gas and an inert gas into the reactor. Furthermore, the method may further include: removing unreacted gases and impurities in the reactor. In this case, unreacted gases and impurities may be removed by creating vacuum inside the reactor, or supplying an inert gas, or repeating a heat treatment, a radiation treatment, a UV treatment, or an ozone treatment once or more.

In another exemplary embodiment, a ratio of the halogen gas and the inert gas may be 10: more than 0 to 1:9.

In another exemplary embodiment, it is possible to inject a gas bonded to a halogen group element during the halogenation. (for example, XeF₂, and the like)

In another exemplary embodiment, a halogen doping amount may be adjusted by adjusting one or more of reaction time, reaction temperature, a mixture ratio of halogen and inert gases, and gas pressure during a halogenation reaction.

In another exemplary embodiment, the inert gas may be selected from nitrogen, argon, helium, and neon.

In another exemplary embodiment, a mixing gas buffer may be used when the mixed gas of the halogen gas and the inert gas is injected.

In another exemplary embodiment, the mixed gas may be injected into the reactor from the mixing gas buffer, such that the pressure of the mixing gas buffer and the pressure in the reactor become the same as each other.

According to exemplary embodiments of the present disclosure, when a halogenated carbon material is prepared, it is possible to dope a halogen at a high concentration within a very short period of time, for example, 60 seconds by using a highly reactive halogen gas or a halogen/inert mixed gas without using a high-temperature and high-pressure plasma, and it is possible to adjust a doping amount of the halogen suitably for the use.

Further, according to exemplary embodiments of the present disclosure, since a carbon material having an oxygen-based functional group, for example, graphene oxide is reduced during a procedure in which the halogen gas is doped, a separate reduction procedure is not particularly needed, and as a result, the process is simple and mass production is easily achieved.

In addition, a halogenated carbon material according to exemplary embodiments of the present disclosure exhibits excellent oxygen reduction reaction characteristics of a fuel cell, which are close to those of platinum due to the inherently high electronegativity, and thus is suitable for replacing platinum which is an obstacle to the commercialization of a fuel cell. Furthermore, it is possible to prevent flooding of an electrode by water produced from a fuel cell reactant at a high water contact angle.

Further, when a halogenated carbon material according to exemplary embodiments of the present disclosure is used as a secondary battery electrode, it is possible to overcome the disadvantages of a carbon-based electrode having a low storage capacity because the halogen is structurally/chemically advantageous in accommodating lithium.

In addition, the halogenated carbon material according to exemplary embodiments of the present disclosure has excellent hole transporting ability when used in an organic or perovskite solar cell.

### BRIEF DESCRIPTION OF THE DRAWINGS

FIG. 1 is a schematic view showing a preparation process according to an exemplary embodiment of the present disclosure.

FIG. 2A is an expected reaction mechanism of a fluorinated carbon material doped with fluorine among halogens in an exemplary embodiment of the present disclosure, and FIG. 2B is a schematic view of a fluorinated carbon material doped with fluorine in an exemplary embodiment of the present disclosure.

FIG. 3 is a graph showing bonding characteristics of fluorine, which are measured by using X-ray photoelectron spectroscopy of a fluorinated graphene (5:5 fluorinated graphene) prepared in the non-limiting Example of the present disclosure.

FIG. 4A is a graph showing XRD peaks of a fluorinated graphene oxide prepared in Example 1 of the present disclosure and a graphene oxide in the Comparative Example of the present disclosure.

FIG. 4B shows a change in ratio of elements calculated by X-ray photoelectron spectroscopy spectrum of a fluorinated graphene oxide prepared in Example 1 of the present disclosure.

FIG. 5 is a cyclic voltammetry measurement result for a fluorinated graphene oxide in the Example of the present disclosure and a graphene oxide in the Comparative Example of the present disclosure.

FIG. 6 shows initial charge and discharge characteristics of lithium secondary batteries prepared in the non-limiting Examples of the present disclosure.

FIG. 7 shows the performances according to the charge and discharge rate of lithium secondary batteries prepared in the non-limiting Examples of the present disclosure.

FIG. 8 shows the long-term stabilities of lithium secondary batteries prepared in the non-limiting Examples of the present disclosure.

FIG. 9 shows oxygen reduction reaction characteristics of fuel cells prepared in the non-limiting Examples of the present disclosure.

FIG. 10 is a photograph showing a water contact angle of a fluorinated graphene (FIG. 10B) prepared in the non-limiting Example of the present disclosure as compared to that of a graphene oxide (FIG. 10A).

FIG. 11 is a current density graph according to the voltage, showing the power generation efficiency of a hole transporting layer of a P3HT:PCBM-based organic solar cell, to which a fluorinated graphene oxide (FGO) of Example 1 of the present disclosure is applied.

### DETAILED DESCRIPTION

Term Description

In the present specification, a carbon material may include graphene, carbon nanotubes, carbon nanofibers, carbon fibers, graphite, and activated carbon, and may be particularly graphene.

As used herein, a basal plane of a carbon material means a surface at the inner side of the edge of the carbon material.

As used herein, the edge of the carbon material means an edge portion of a plane in which carbon atoms form a hexagonal cyclic structure as a base.

As used herein, a carbon material into which an oxygen-based functional group is introduced means that a carbon material such as graphene, carbon nanotubes, carbon fibers, graphite, and activated carbon includes a structure in which oxygen is bonded to carbon, such as epoxide (C—O—C), ketone (C═O), carboxyl (C—OOH), and a hydroxyl group (C—OH). For example, graphene oxide is a carbon material into which an oxygen-based functional group is introduced.

In the present specification, Y is a halogen such as F, Cl, Br, and I, and preferably F.

As used herein, the doping of a carbon material into which an oxygen-based functional group is introduced with a halogen means that the oxygen-based functional group of the carbon material is reduced, and carbon is reacted with halogen atoms to bond the halogen atom to the carbon material.

As used herein, the etching of a carbon material with a halogen means that when the carbon material is doped with the halogen, the halogen atoms are injected in an excessive amount which is equal to or more than that of halogen reacted with hydrogen atoms (H) or oxygen atoms (O), and as a result, a bond between halogen and carbon is rather broken, CY, CY₂, CY₃, and the like are modified into a structure in which CY, CY₂, CY₃, and the like can be evaporated, and are removed.

### Description of Exemplary Embodiments

Hereinafter, exemplary embodiments of the present disclosure will be described in detail.

A halogen has a high electron negativity, so that when a carbon material such as graphene is doped with the halogen, the catalytic activity and band gap may be enhanced. However, doping with a halogen, particularly, fluorine is not easily performed due to the inherent explosiveness and toxicity of fluorine. Thus, it can be contemplated to indirectly dope the carbon material through an acid (for example, hydrofluoric acid (HF) in the case of fluorine). However, when the carbon material is doped with an acid, the degree of acid doped into the carbon material is not increased due to the reactivity limitation, it is difficult to adjust a halogen doping amount, and it is also difficult to achieve mass production.

Thus, in exemplary embodiments, the present disclosure provides a method for preparing a halogenated carbon material, the method comprising: introducing a halogen gas, a gas including a halogen element, or a mixed gas of a halogen gas and an inert gas into a carbon material having an oxygen-based functional group, thereby reducing and simultaneously halogenating the carbon material having an oxygen-based functional group via a chemical reaction of the carbon material having an oxygen-based functional group and the halogen gas, the gas including a halogen element, or the mixed gas of the halogen gas and the inert gas.

Unlike acids including a halogen, such as hydrochloric acid or hydrofluoric acid, the halogen gas undergoes a substitution reaction with H or O, and the like which are bonded to a carbon material having an oxygen-based functional group to enable fluorine atoms to be uniformly doped onto the entire area.

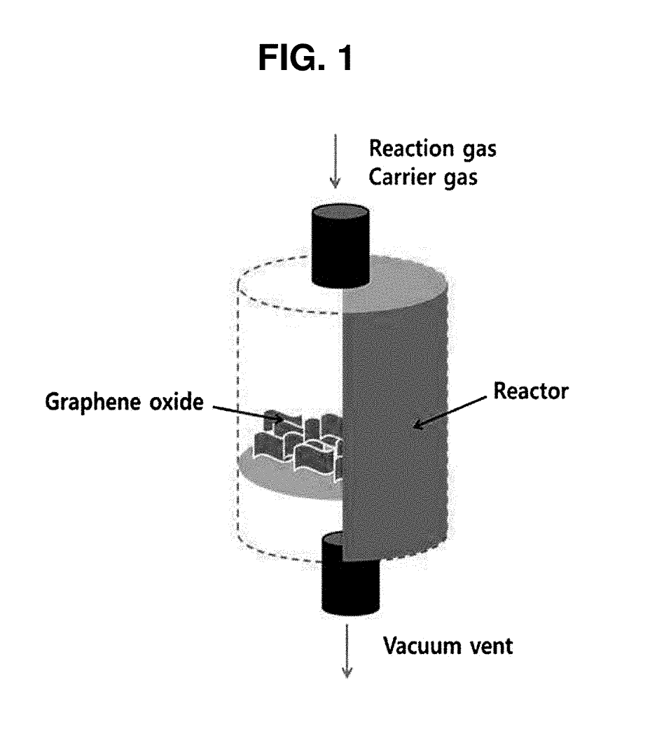

FIG. 1 is a schematic view showing a preparation process according to an exemplary embodiment of the present disclosure. FIG. 1 shows a batch process, but it is needless to say that the preparation can be performed by a continuous process.

Referring to FIG. 1, moisture, and gases which cause side reactions, are removed by putting a carbon material having an oxygen-based functional group into a reactor, and creating a nitrogen purged or vacuum atmosphere.

Here, the carbon material having an oxygen-based functional group is, for example, a material to which an oxygen functional group is bonded in the carbon material, or a material into which an oxygen-based functional group can be introduced through a post-treatment.

In the non-limiting example, the carbon material having an oxygen-based functional group may be one or more of graphene oxide, carbon nanotube oxide, carbon nanofiber oxide, activated carbon oxide, and graphite oxide.

In order to enable halogen atoms to be doped onto the entire surface of the carbon material as described above, the carbon material needs to include an oxygen-based functional group not only at the edge, but also on the basal plane.

Further, in an exemplary embodiment, the carbon material may include an oxygen-based functional group at a predetermined content, for example, 3% or more or 3% to 35% or 30% to 35%. For reference, for example, since pure graphite hardly contains H or O, it is difficult for a fluorine gas to be substituted, so that the entire surface of the carbon material is not doped with fluorine, and even though the carbon material is doped, only a portion of the edge is doped.

Next, the reaction is performed by injecting a halogen gas or a mixed gas of a halogen gas/an inert gas.

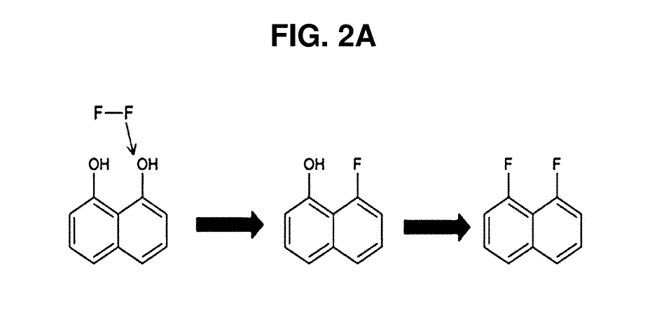

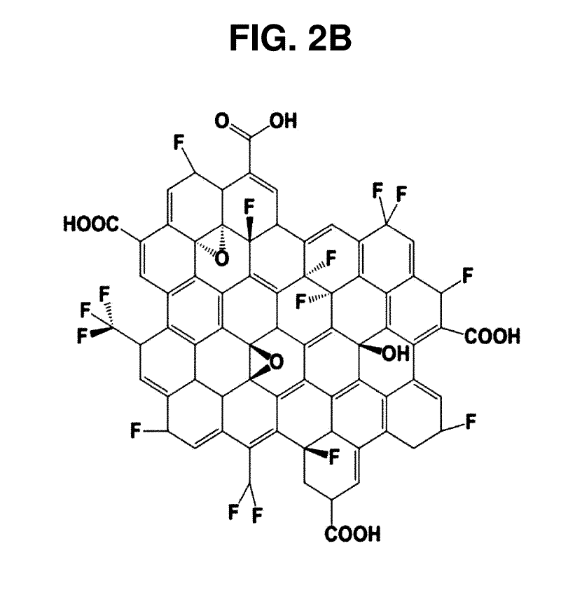

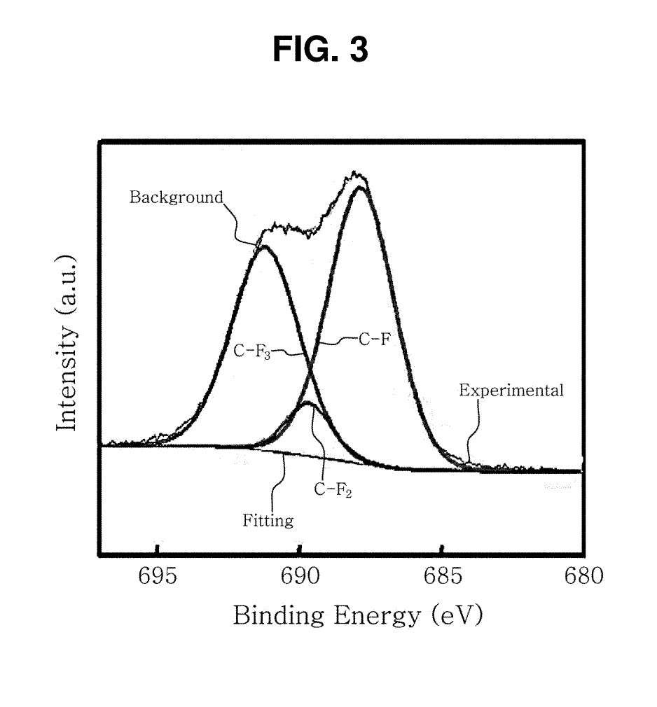

FIG. 2A is an expected reaction mechanism of a fluorinated carbon material doped with fluorine among halogens in an exemplary embodiment of the present disclosure, and FIG. 2B is a schematic view of a fluorinated carbon material doped with fluorine in an exemplary embodiment of the present disclosure.

As shown in FIG. 2 which describes the doping with fluorine as an example, it is contemplated that the highly reactive fluorine in the fluorine/inert mixed gas is preferentially reacted (substitution reaction) with primarily relatively unstable oxygen-based groups to reduce the carbon material having an oxygen-based functional group, and subsequently, the doping with fluorine occurs. However, in the case of excessive doping, it appears that the fluorine gas is reacted with carbon atoms in the carbon material to produce CF₂ and CF₃, and the etching occurs. Accordingly, only the doping with halogen needs to be performed while the etching does not occur. That is, when the halogen is reacted with hydrogen atoms (H) or oxygen atoms (O) to inject the halogen atoms in an excessive amount which is equal to or more than that of halogen reacted with hydrogen atoms (H) or oxygen atoms (O) and substituting those atoms, there occurs an etching in which a bond between halogen and carbon is rather broken, so that even though the entire surface including the edge and basal plane of the carbon material is doped, the doping with halogen needs to be adjusted, such that the entire surface is not etched.

Meanwhile, when fluorine is included alone, the doping with fluorine or destruction of the graphene structure rapidly occurs, and as a result, it is difficult to adjust the doping, so that it is preferred that an inert gas is contained to adjust the reaction rate of fluorine.

Meanwhile, in another exemplary embodiment, a mixing gas buffer may be used when the mixed gas of the halogen gas and the inert gas is injected.

Further, in another exemplary embodiment, the mixed gas may be injected into the reactor from the mixing gas buffer, such that the pressure of the mixing gas buffer and the pressure in the reactor become the same as each other.

In another exemplary embodiment, the halogen doping ratio may be adjusted by adjusting a ratio of the halogen gas and the inert gas.

In another exemplary embodiment, a ratio of the halogen gas and the inert gas may be 10: more than 0 to 1:9. When the halogen gas is used at 100% (10:0), there is a problem in that the conductivity of the carbon material deteriorates because the etching of carbon atoms occurs. In contrast, when the halogen gas is used at less than 10% (1:9), the carbon material is not properly doped with a halogen.

In another exemplary embodiment, as the inert gas used in the mixed gas, nitrogen, argon, helium, neon, and the like may be used.

Meanwhile, according to the flow rate or pressure of a gas, the reaction time (gas exposure time), and the temperature in addition to the ratio of fluorine and an inert gas, it is possible to adjust the fluorine doping amount and the resulting reduction degree.

In another exemplary embodiment, the halogenation of the carbon material having an oxygen-based functional group may be performed for 1 to 3,600 seconds, preferably 5 to 600 seconds.

In another exemplary embodiment, the fluorination of the carbon material having an oxygen-based functional group may be performed under a gas pressure of 0.001 atm to 100 atm. For reference, pressure is associated with the reaction rate of reactants in a gas phase reaction, and when pressure is high, the fluorine doping amount is increased, and carbon may be etched under a predetermined pressure or more. When the content of fluorine is increased, the content of oxygen may be dropped to about 10%.

In another exemplary embodiment, the fluorination of the carbon material having an oxygen-based functional group may be performed at a gas flow rate of 1 m/min to 1,000 ml/min.

In another exemplary embodiment, the fluorination of the carbon material having an oxygen-based functional group may be performed at a temperature of 88 K to 773 K.

The synthesis conditions of reaction time, reaction temperature, mixture ratio of halogen/inert gas, and gas pressure during a halogenation reaction affect the halogen doping amount. Further, the above-described reaction time, reaction temperature, mixture ratio of halogen/inert gas, and mixture gas pressure may vary depending on the crystallinity of the carbon material, the surface functional group, and the like. Accordingly, in order to obtain a desired halogen doping amount, the reaction time, reaction temperature, mixture ratio, gas pressure, and the like may be adjusted in consideration of the crystallinity of the carbon material, the surface functional group, and the like.

Specifically, when the crystallinity of the carbon material is high, a mixture gas having a relatively high halogen content needs to be used, the reaction time needs to be long, and the temperature also needs to be high because the doping needs to be performed while some carbon atoms are etched.

Further, when H or 0 is present in a large amount in the surface functional group, a reaction with the halogen proceeds well, and as a result, the halogen content may be lowered, and accordingly, it is possible to shorten the reaction time and allow the temperature to be set at room temperature.

In addition, in relation to the mixture ratio of halogen/inert gas, the higher the content of halogen, the faster the reaction proceeds, so that in this case, the reaction time may be shortened and the reaction temperature may also be lowered.

In a non-limiting example, it is possible to adjust one or more parameters selected from the synthesis conditions of reaction time, reaction temperature, mixture ratio of halogen/inert gas, and gas pressure during a halogenation reaction, such that the electrical conductivity is enhanced, and a content (for example, about 10 atomic %) of oxygen capable of being dispersed in a solution is implemented while an optimal content (for example, 10 to 12 atomic %) of halogen doping atom in the carbon material may be set.

Meanwhile, in another exemplary embodiment, unreacted gases and impurities may be removed by creating vacuum inside the reactor after a halogenation reaction, or supplying an inert gas for a long period of time, or repeating a heat treatment, a radiation treatment, a UV treatment, or an ozone treatment once or more.

A halogen-doped carbon material obtained by being subjected to the aforementioned procedure may be a carbon material, in which the entire surface including a basal plane and an edge is doped with a halogen, and may be a carbon material including one or more selected from a group consisting of C—Y, C—Y₂, and C—Y₃, particularly, C—Y₃.

Further, in another exemplary embodiment, the halogen-doped carbon material includes all of C—Y, C—Y2, and C—Y₃.

In addition, in another exemplary embodiment, the halogen-doped carbon material includes C—Y, C—Y₂, and C—Y₃, on the edge and the basal plane, includes C—Y₃ in a large amount particularly on the edge, and includes C—Y in a large amount on the basal plane.

In contrast, in the case of a prior art in which the edge is only doped with a halogen, the content of the halogen is so low, for example, 3% to 4%, and only C—Y is present on the edge in terms of bond form. Further, in this case, characteristics as an energy device significantly deteriorate, so that the device may not be utilized as an energy device.

For reference, again referring to FIG. 2B showing an example of doping with fluorine, the carbon material is a carbon material in which the entire surface including the basal plane and the edge is doped with fluorine, and includes C—Y, C—Y₂, and C—Y₃ on the edge and the basal plane, includes C—Y₃, in a large amount particularly on the edge, and includes C—Y in a large amount on the basal plane.

In another exemplary embodiment, the halogen-doped carbon material may have a halogen doping amount of 30% or more. Here, the doping amount is a percentage based on an atomic ratio of halogen atoms to carbon atoms in a carbon material. As described above, the carbon material is useful as an energy device.

The halogen-doped carbon material according to exemplary embodiments of the present disclosure is useful as an energy device.

That is, electronic characteristics (positively charged, electroneutrality-break, and spin-density changed carbon materials) of a carbon material may be changed by partially doping only the edge of the carbon material having an oxygen-based functional group with a halogen, and doping the entire area including the basal plane with a halogen in an atomic unit. In addition, in a carbon material, a functional group other than carbon present even on the basal plane may be substituted with a halogen and removed to enhance the electrical conductivity of the carbon material and minimize the electric loss caused by resistance.

In another exemplary embodiment, the energy device may be an energy device such as a fuel cell, a secondary battery, a fuel cell, and a supercapacitor, particularly preferably a fuel cell or a lithium ion battery or an organic or perovskite solar cell.

More specifically, the energy device may be used as a material for an energy device, such as a fuel cell oxygen reduction reaction catalyst such as PEMFC, DMFC, and AFC, an electrode of a secondary battery such as a lithium ion battery, a hole transporting layer and an electrode of a solar cell such as an organic photovoltaic cell (OPV), and an electrode of a supercapacitor such as an electrochemical double layer capacitor (EDLC).

In another exemplary embodiment, in the case of a hole transporting layer of an organic photovoltaic cell, the hole transporting layer may be formed through a spin coating after a fluorinated graphene prepared through the method is dissolved in a solvent.

Furthermore, when an energy device is applied to a lithium ion battery or a fuel cell, the energy device can be prepared by coating a film such as a conductive metal and a polymer with a fluorinated graphene dispersed in a solvent.

Hereinafter, a specific example according to exemplary embodiments of the present disclosure will be described in more detail. However, the present disclosure is not limited to the following Example, and various forms of examples can be implemented within the accompanying claims, and it is to be understood that the following Example only completes the disclosure of the present disclosure and allows a person with ordinary skill in the art to easily carry out the present disclosure.

### EXAMPLES AND COMPARATIVE EXAMPLES

### Preparation of Fluorinated Graphene Oxide (FGO) (Example)

Graphene oxide being a carbon material was doped with fluorine as follows. In the present Example, the preparation was performed by a batch method (see FIG. 1), and it is needless to say that the preparation can be performed by a continuous process.

First, an N2/F2 mixing buffer was purged with N2. Subsequently, 0.5 g of graphene oxide was put into a reactor, and then the reactor was purged with N2. After the N2/F2 mixing buffer purge, N2 was vented out. Since then, the molar ratio of N2/F2 was variously adjusted to 10:0, 9:1, 8:2, 7:3, 6:4, 5:5, 4:6, 3:7, 2:8, and 1:9 by introducing F2 into the mixing buffer.

After completion of mixing of N2/F2, a raw material gas was flowed slowly into the reactor. The raw material gas was flowed until pressures of the reactor and the mixing buffer became the same as each other, and then an additional reaction was performed for about 30 minutes. After termination of the additional reaction, the reactor was purged with N2 in order to remove the remaining F2 gas in the reactor. After termination of purging with N2, fluorine-doped graphene was recovered from the reactor.

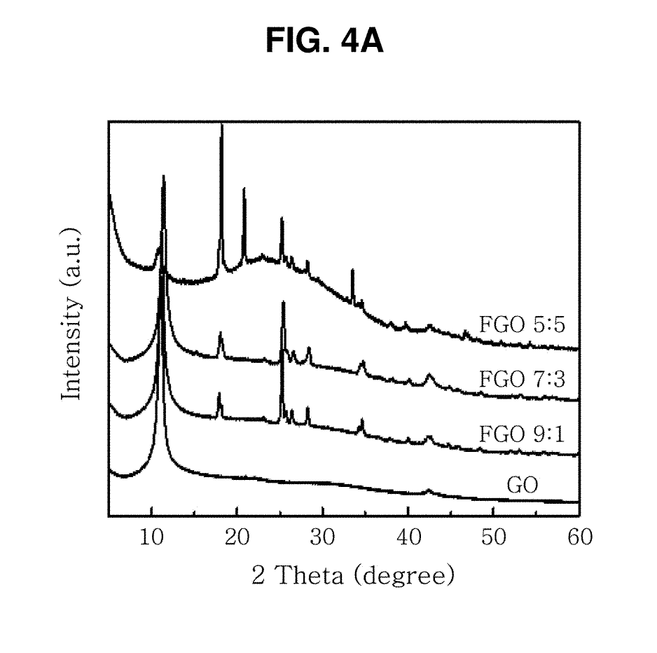

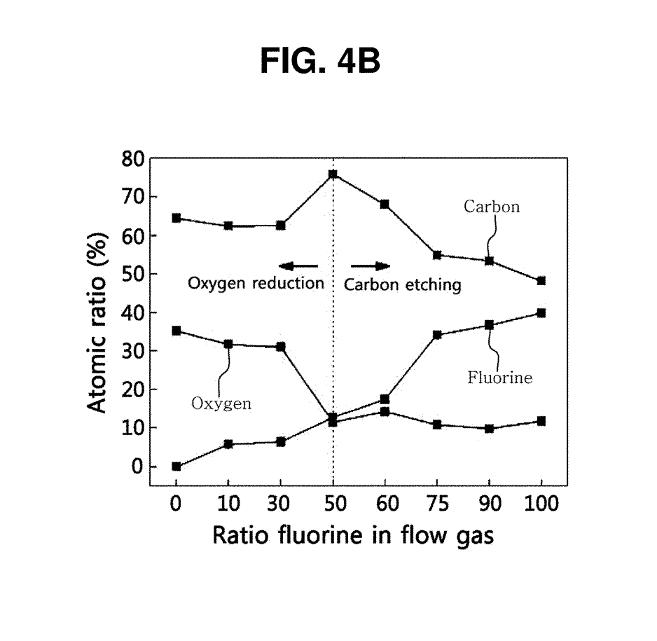

FIG. 4A is a graph showing XRD peaks of a fluorinated graphene oxide prepared in Example 1 of the present disclosure and a graphene oxide in the Comparative Example of the present disclosure.

In FIG. 4A, FGO 5:5, FGO 7:3, and FGO 9:1 are the case where the molar ratio of F2/N2 is 5:5, 7:3, and 9:1, respectively.

As can be known from FIG. 4A, as doping with a gas having a high content of fluorine was performed, the peak of graphene oxide appearing at 11.8° gradually disappeared, and a clear peak was observed at 26° showing the crystallinity of a carbon material. Further, unlike a typical carbon or a carbon material doped with a heterogeneous element, peaks were observed at various 2 thetas, and it is determined that these peaks are attributed to the binding characteristics and structure of fluorine.

FIG. 4B shows a change in ratio of elements calculated by X-ray photoelectron spectroscopy spectrum of a fluorinated graphene oxide prepared in Example 1 of the present disclosure.

As shown in FIG. 4B, it can be confirmed that as the mixture ratio of fluorine/inert gas is increased, the amount of oxygen-based functional group is decreased, and the amount of fluorine added is increased.

That is, as the ratio of fluorine gas is increased, the content of fluorine is increased, and C—F, C—F₂, and C—F₃ Peaks are evenly produced. For reference, it can be seen that in the case of doping with fluorine, which uses an existing ball mill method (Non-Patent Document 1), doping occurs only at the edge of graphene, and only C—F bonds are produced, whereas fluorine-doped graphene oxide (FGO) produced in exemplary embodiments of the present disclosure has various bonding forms of C—F, C—F₂, and C—F₃. In particular, it can be seen that C—F is produced intensively on the graphene basal plane, and C—F₃ is produced intensively on the edge.

### Graphene Oxide (Comparative Example)

Meanwhile, graphene oxide, which was subjected to the aforementioned fluorine doping process, was used as the Comparative Example.

[Evaluation of Characteristics]

Measurement of Capacitance

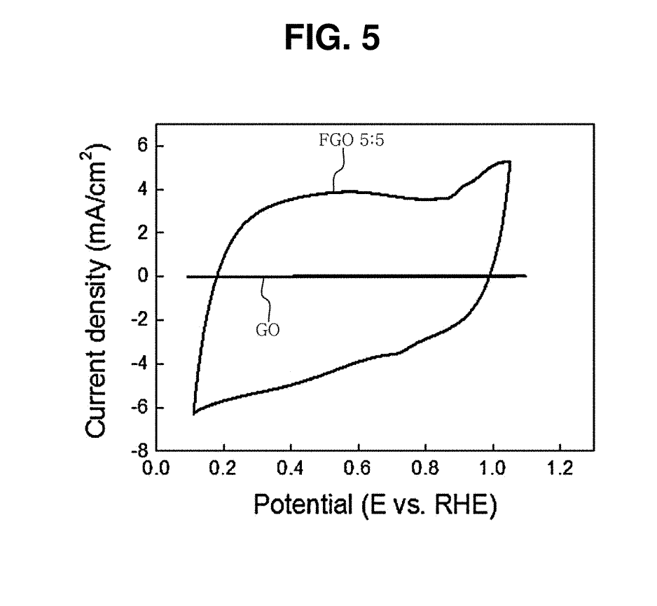

FIG. 5 is a cyclic voltammetry measurement result for a fluorinated graphene oxide in the Example of the present disclosure and a graphene oxide in the Comparative Example of the present disclosure.

As shown in FIG. 5, it was confirmed that for the fluorinated graphene oxide in the Example and the graphene oxide in the Comparative Example, as a result of measurement by cyclic voltammetry at 50 mV/s in a 0.1 M KOH solution, the electrochemical surface area was increased by about 400 times. An existing GO had a capacitance of about 0.8 F/g, which is a insignificantly small number, but FGO in the Example, in which doping with fluorine was performed, had a capacitance of about 320 F/g, showing an excellent performance.

Preparation and Characteristic Analysis of Lithium Ion Battery Electrode

A lithium ion battery electrode was prepared by using the fluorinated graphene oxide prepared in Example 1, and the characteristics thereof were analyzed.

After fluorinated graphene oxide (active material): polyvinyldifluoride (PVDF)(a material which maintains the form of an electrode): super P (conductive material) were mixed at 8:1:1, the resulting mixture was dispersed in an N-methyl-2-pyrrolidone (NMP) solvent, and then stirred by using ultrasonic wave for a predetermined time.

Meanwhile, as a comparative example in which fluorinated graphene oxide was not included, (graphene oxide) was used.

The prepared solution was coated to a thickness of 0.5 mm on a copper foil, and then dried in a vacuum oven. A lithium foil was used as a positive electrode, #2325 manufactured by Celgard, LLC was used as a separation membrane, and 1 M LiPF6 (EC: DEC=1:1) was used as an electrolyte. Besides, for parts of a coin cell, cells were prepared in a glove box under an argon atmosphere by using CR2032 products manufactured by Wellcos Corp.

A coin cell was prepared by using the prepared electrodes, and then the performance of a battery was evaluated through a charge-discharge experiment. Under the charge-discharge conditions, a capacity when the current density was 50 to 800 mA g⁻¹, and a long-term stability when the current density was 400 mA g⁻¹ were analyzed.

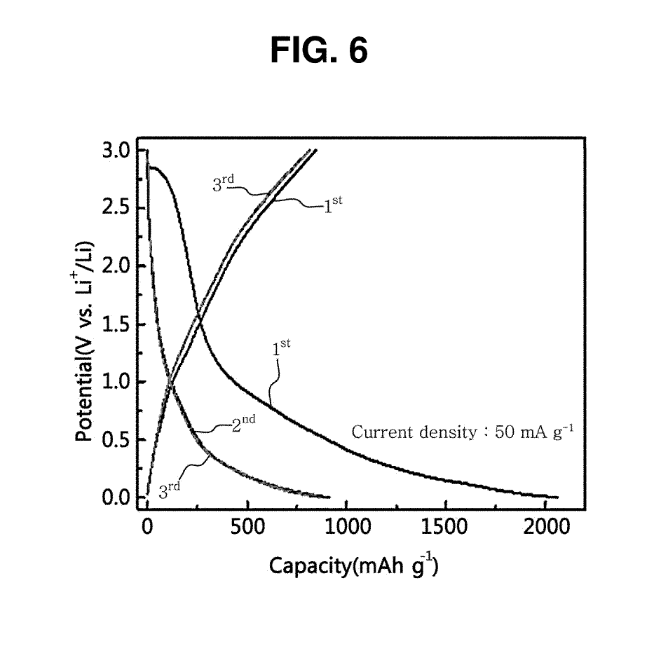

FIG. 6 shows initial charge and discharge characteristics of lithium secondary batteries prepared in the non-limiting Examples of the present disclosure, and shows the first cyclic voltage-capacity of the sample prepared under a condition in which the ratio of a fluorinated gas and a nitrogen gas was 5:5.

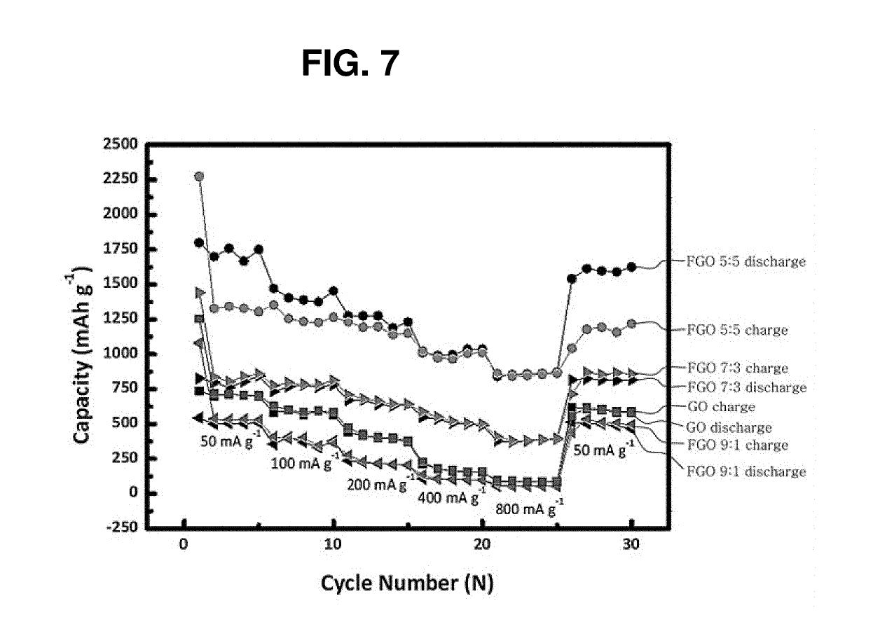

FIG. 7 shows the performances according to the charge and discharge rate of lithium secondary batteries prepared in the Examples of the present disclosure, and is a graph in which the capacity-charge and discharge is repeated when the current density was 50 to 800 mA g⁻¹ according to the ratio of a fluorinated gas and a nitrogen gas.

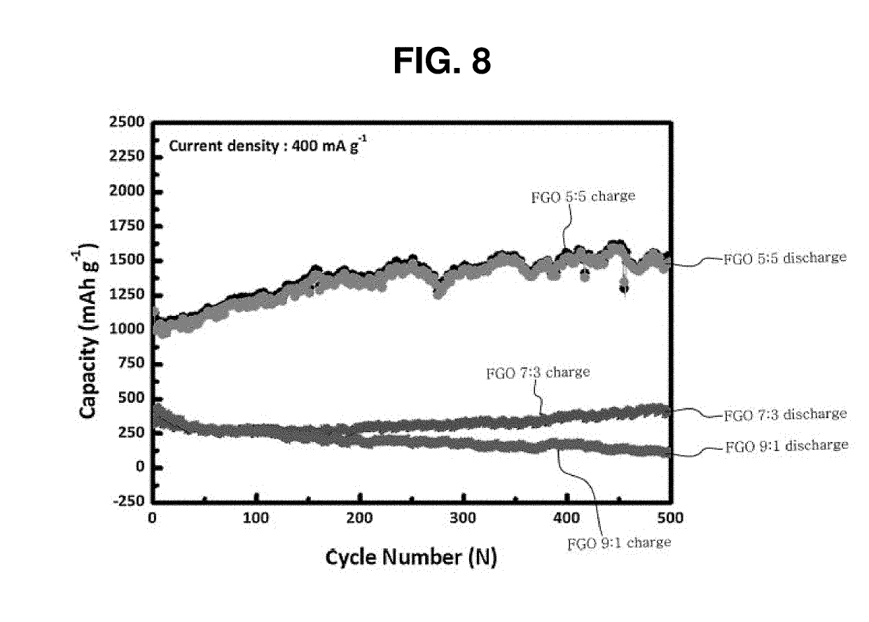

FIG. 8 shows the long-term stabilities of lithium secondary batteries prepared in the Examples of the present disclosure.

As can be seen in FIGS. 6 to 8, when the current density was 50 mA g⁻¹, the capacity of lithiation/delithiation was 2274.6 mAh g⁻¹ and 1798.6 mAh g⁻¹, respectively. When the current density is 50, 100, 200, 400, and 800 mA g⁻¹, it can be seen that as the ratio of fluorine is increased, the high capacity is measured. As the ratio of the treated fluorine gas is increased, a discharge capacity of 1434.9, 303, and 177.5 mAh g⁻¹ (current density of 400 mA g⁻¹, 250 cycles) is exhibited. It can be confirmed that the long-term performance of the fluorinated graphene oxide is maintained regardless of the content of fluorine gas, but the long-term stability of a fluorinated graphene oxide prepared at a ratio of 5:5 show the best result.

It can be seen that the fluorinated carbon material as described above shows high lithium ion storage capability and durability, and thus is suitable as a material for a lithium ion battery electrode.

Preparation and Oxygen Reduction Reaction Characteristics of Fuel Cell Electrode

At this time, oxygen reduction reaction characteristics for a fuel cell electrode of the fluorinated graphene oxide previously prepared were analyzed.

Specifically, about 30 mg of the fluorinated graphene oxide was dispersed in 1 ml of dimethyl sulfoxide (DMF) through ultrasonic dispersion (sonication), and then an ink for electrochemical analysis was prepared by adding about 0.1 ml of a Nafion solution as a binder thereto.

5 μl of the ink was dropped onto a glassy carbon electrode for electrochemical analysis, and then dried to prepare an electrode for analysis. The scan rate and the electrode rotation rate were fixed at 5 mV/s and 1,600 rpm, respectively in a 0.1 M KOH solution by using a potentiostat.

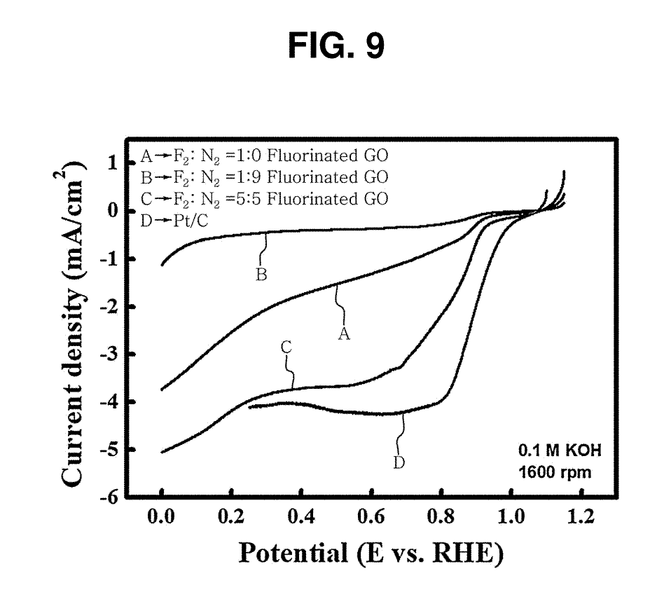

FIG. 9 shows oxygen reduction reaction characteristics of fuel cells using fluorinated graphene oxide prepared in the Examples of the present disclosure.

As shown in the electrochemical oxygen reduction reaction result in FIG. 9, it can be confirmed that the fuel cells using the fluorinated graphene oxide shows high electrochemical oxygen reduction reaction characteristics similar to those of an existing platinum catalyst.

That is, when compared to the platinum catalyst, the fuel cells show low onset potential (0.06 V compared to the platinum catalyst) and high current density (4 mA/cm²).

Meanwhile, it was confirmed whether the fluorinated graphene oxide had hydrophilicity/hydrophobicity, and the like by measuring the water contact angle of the fluorinated graphene oxide as compared to that of graphene oxide. Specifically, the angle of a water drop between water drop and fluorinated graphene was measured (a photograph was taken and an angle was measured by a program) by coating a silicon wafer substrate (a substrate such as quartz can also be used) with fluorinated graphene oxide, and then dropping a water drop thereon.

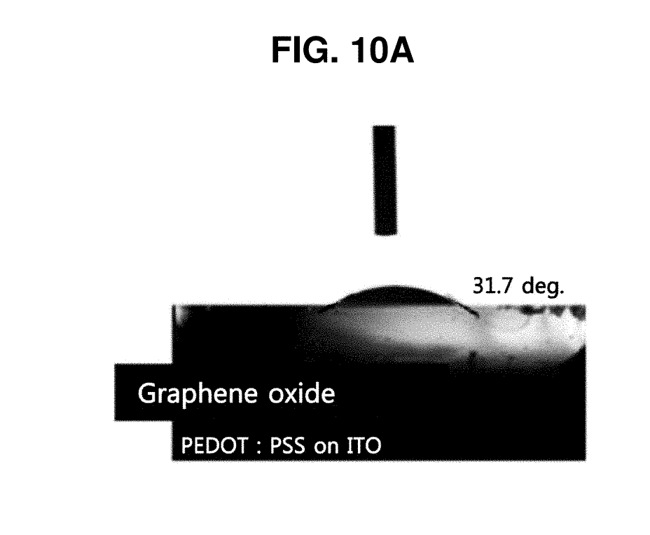

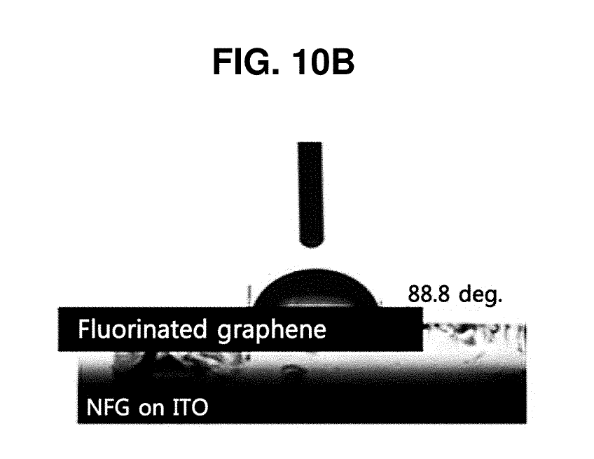

FIG. 10 is a photograph showing a water contact angle of a fluorinated graphene oxide (FIG. 10B) prepared in the Example of the present disclosure as compared to that of a graphene oxide (FIG. 10A).

As a result, the water contact angle of the fluorinated graphene oxide was much higher than that of graphene oxide, and there is an advantage in that it is possible to prevent flooding in which water covers the surface of the electrode in the fuel cell anode due to the high contact angle.

Application and Characteristic Analysis of Solar Cell

Meanwhile, the power generation efficiency was confirmed by applying the fluorinated graphene oxide (FGO) prepared in Example 1 to a hole transporting layer of a P3HT:PCBM-based organic photovoltaic cell.

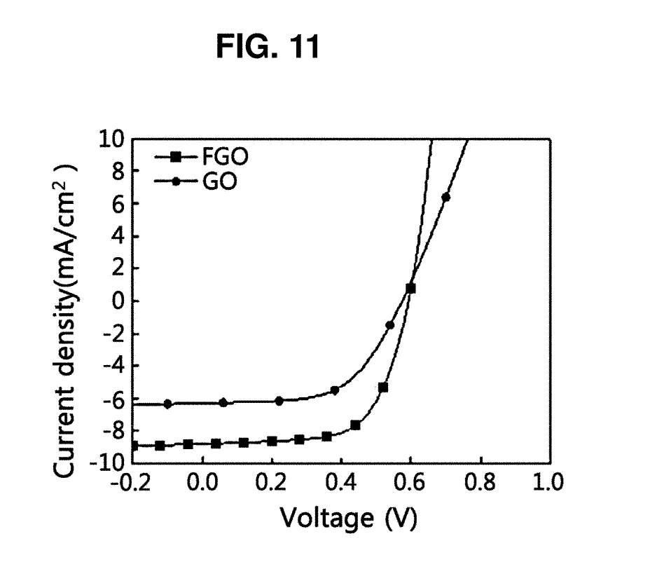

FIG. 11 is a current density graph according to the voltage, showing the power generation efficiency of a hole transporting layer of a P3HT:PCBM-based organic photovoltaic cell, to which a fluorinated graphene oxide (FGO) of Example 1 of the present disclosure is applied. In FIG. 11, the current density graph of graphene oxide (GO) is together marked.

As shown in FIG. 11, a power generation efficiency of about 3.32% was confirmed when the fluorinated graphene oxide (FGO) in Example 1 of the present disclosure was applied. It is determined that the band gap of graphene is increased due to doping with fluorine, and as a result, the increase in band gap plays a more appropriate role in transporting holes.

What is claimed is:

1. An energy device comprising:
a halogen (Y)-doped carbon material,
wherein the halogen-doped carbon material comprises one or more selected from a group consisting of C—Y₂ and C—Y₃.

2. The energy device according to claim 1, wherein the halogen-doped carbon material comprises all of C—Y, C—Y₂, and C—Y₃.

3. The energy device according to claim 1, wherein for the halogen-doped carbon material, an entire surface of the carbon material, which comprises a basal plane and an edge, is doped with a halogen.

4. The energy device according to claim 1, wherein the halogen-doped carbon material comprises C—Y, C—Y₂, and C—Y₃, on an edge and a basal plane, comprises C—Y₃, on the edge, and comprises C—Y on the basal plane.

5. The energy device according to claim 1, wherein the energy device is a fuel cell, a lithium ion battery, an organic photovoltaic cell, or an electrochemical double layer capacitor.

6. The energy device according to claim 5, wherein the energy device is a fuel cell, and the halogen-doped carbon material is a fuel cell electrode catalyst.

7. The energy device according to claim 5, wherein the energy device is a lithium ion battery, and the halogen-doped carbon material is a lithium ion battery negative electrode material.

8. The energy device according to claim 5, wherein the energy device is an organic solar cell, and the halogen-doped carbon material is a material for a hole transporting layer.

9. The energy device according to claim 1, wherein the carbon material comprises an oxygen-based functional group at 3% or more or 3% to 35%.

10. The energy device according to claim 1, wherein the carbon material comprises an oxygen-based functional group, and is one or more selected from a group consisting of graphene oxide, carbon nanotube oxide, carbon nanofiber oxide, activated carbon oxide, and graphite oxide.

11. The energy device according to claim 1, wherein the halogen (Y) is fluorine (F).

12. A method for preparing a halogenated carbon material, the method comprising: introducing a halogen gas or a mixed gas of a halogen gas and an inert gas into the carbon material having an oxygen-based functional group, thereby reducing the carbon material having an oxygen-based functional group and doping a halogen into the carbon material.

13. The method according to claim 12, wherein when a halogenation proceeds, etching of the carbon material is made not to proceed.

14. The method according to claim 12, wherein the method comprises:
putting the carbon material having an oxygen-based functional group into a reactor and allowing the reactor to be in vacuum state; and reducing and halogenating the carbon material having an oxygen-based functional group by injecting the halogen gas or the mixed gas of a halogen gas and an inert gas into the reactor.

15. The method according to claim 14, wherein the method further comprises: removing unreacted gases and impurities in the reactor.

16. The method according to claim 15, wherein unreacted gases and impurities are removed by creating vacuum inside the reactor, or supplying an inert gas, or repeating a heat treatment, a UV treatment, or an ozone treatment once or more.

17. The method according to claim 12, wherein a ratio of the halogen gas and the inert gas may be 10: more than 0 to 1:9.

18. The method according to claim 12, wherein the inert gas is selected from nitrogen, argon, helium, and neon.

19. The method according to claim 12, wherein a halogen doping amount is adjusted by adjusting one or more of reaction time, reaction temperature, a mixture ratio of halogen and inert gases, and gas pressure.

20. The method according to claim 14, wherein a mixing gas buffer is used when the mixed gas of the halogen gas and the inert gas is injected.
